(19) United States
(12) Patent Application Publication
(10) Pub. No.: US 2011/0266627 A1
(43) Pub. Date: Nov. 3, 2011

(54) SEMICONDUCTOR DEVICE

(76) Inventors: Seung-hun Lee, Seoul (KR); Byeong-chan Lee, Yongin-si (KR); Sung-kwan Kang, Seoul (KR); Keum-seok Park, Gwangmyeong-si (KR); Yu-gyun Shin, Seongnam-si (KR); Sun-ghil Lee, Hwaseong-si (KR)

(21) Appl. No.: 13/096,311

(22) Filed: Apr. 28, 2011

(30) Foreign Application Priority Data
Apr. 29, 2010 (KR) 10-2010-0040226

(51) Int. Cl. H01L 27/092; H01L 27/085

(52) U.S. Cl. 257/369; 257/368; 257/288; 257/E27.06; 257/E27.062

(57) ABSTRACT

A semiconductor device includes a semiconductor substrate including a plurality of active areas defined by a device isolation layer, a gate line structure crossing the plurality of active areas, a buffer insulation layer on the semiconductor substrate, the buffer insulation layer contacting a portion of a side of the gate line structure, a contact etching stopper layer on the buffer insulation layer, and a contact plug passing through the buffer insulation layer and the contact etching stopper layer to be connected to the plurality of active areas.

### CROSS-REFERENCE TO RELATED APPLICATIONS

Korean Patent Application No. 10-2010-0040226, filed on Apr. 29, 2010, in the Korean Intellectual Property Office, and entitled: “Semiconductor Device,” is incorporated by reference herein in its entirety.

### BACKGROUND

1. Field

The inventive concept relates to a semiconductor device, and more particularly, to a semiconductor device including a transistor with improved electrical characteristics.

2. Description of the Related Art

With the development of the semiconductor industries and the demand of users, highly integrated and high performance electronic devices are manufactured more and more. Accordingly, semiconductor devices, which are core components of electronic devices, are also required to be highly integrated and have a high performance. However, as the semiconductor devices are highly integrated, a size of a transistor included in the semiconductor devices is reduced, and thus, electrical characteristics of the transistor may be reduced.

### SUMMARY

According to an aspect of the inventive concept, there is provided a semiconductor device. The semiconductor device may include a semiconductor substrate having a plurality of active areas defined by a device isolation layer, a gate line structure crossing the plurality of active areas, a buffer insulation layer formed on the semiconductor substrate so as to contact a portion of a side of the gate line structure, a contact etching stopper layer formed on the buffer insulation layer, and a contact plug that passes through the buffer insulation layer and the contact etching stopper layer to be connected to the plurality of active areas.

The contact etching stopper layer may cover the gate line structure.

The buffer insulation layer may have a predetermined thickness, the predetermined thickness overlapping a portion of a lateral lower side of the gate line structure.

The gate line structure may include a conductive gate line, a capping layer on the conductive gate line, and a spacer layer covering sides of the conductive gate line and the capping layer.

The buffer insulation layer may overlap a portion of a side of the spacer layer.

The buffer insulation layer may have a predetermined thickness, the predetermined thickness overlapping a portion of a lateral lower side of the spacer layer.

The contact etching stopper layer may be on the capping layer and the spacer layer.

The contact etching stopper layer may have a bottom surface that is higher than an upper surface of the active areas.

An upper surface of the buffer insulation layer may be higher than an upper surface of the active areas.

A portion of the buffer insulation layer on the device isolation layer may have a bottom surface that is lower than an upper surface of the active areas.

The semiconductor substrate may include a trench with a device isolation layer therein, the device isolation layer including a trench buffer oxide layer and a trench liner nitride layer sequentially covering inner surfaces of the trench, and a buried oxide layer filing the trench.

The trench liner nitride layer and the contact etching stopper layer may be spaced apart from each other, the buffer insulation layer being between the trench liner nitride layer and the contact etching stopper layer.

The buffer insulation layer may have the same thickness as the contact etching stopper layer.

A thickness of the buffer insulation layer may be greater than a thickness of the contact etching stopper layer.

The semiconductor device may further include an interlayer insulation layer covering the contact etching stopper layer, wherein the contact plug passes through the interlayer insulation layer to be connected to the active areas.

An upper surface of the interlayer insulation layer may be higher than an upper surface of the gate line structure.

The buffer insulation layer may include an oxide.

The contact etching stopper layer may include a nitride.

The buffer insulation layer may surround a lower portion of the gate line structure.

According to an aspect of the inventive concept, there is provided a semiconductor device. The semiconductor device may include a gate structure on a semiconductor substrate, a buffer insulation layer on the semiconductor substrate, a portion of the buffer insulation layer overlapping an active area in the semiconductor substrate, a contact etching stopper layer on the buffer insulation layer, the buffer insulation layer separating the active area and the contact etching stopper layer, and a contact plug passing through the buffer insulation layer and the contact etching stopper layer to be connected to the active area.

According to an aspect of the inventive concept, there is provided a semiconductor device. The semiconductor device may include a semiconductor substrate having an n-type area with an n-type transistor, a p-type area with a p-type transistor, and a plurality of active areas defined by a device isolation layer, a gate line structure crossing the plurality of active areas, a buffer insulation layer that is formed in the p-type area of the semiconductor substrate and contacts a portion of a side of the gate line structure, a contact etching stopper layer formed on the semiconductor substrate and the gate line structure to cover the buffer insulation layer, and a contact plug that passes through the contact etching stopper layer to be connected to the plurality of active areas and formed in each of the p-type area and the n-type area.

The contact plug formed in the p-type area may pass through the contact etching stopper layer and the buffer insulation layer to be connected to the active areas.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a plan view of forming a trench in a method for manufacturing a semiconductor device according to an embodiment;

FIG. 2 illustrates a cross-sectional view along line II-II of FIG. 1;

FIG. 3 illustrates a cross-sectional view of forming an insulation material layer in a method for manufacturing a semiconductor device according to an embodiment;

FIG. 4 illustrates a cross-sectional view of forming a device isolation layer in a method for manufacturing a semiconductor device according to an embodiment;

FIG. 5 illustrates a plan view of forming a gate line structure in a method for manufacturing a semiconductor device according to an embodiment;

FIG. 6 illustrates a cross-sectional view of forming a gate line structure in a method for manufacturing a semiconductor device according to an embodiment;

FIG. 7 illustrates a cross-sectional view of forming a gate line structure in a method for manufacturing a semiconductor device according to an embodiment;

FIG. 8 illustrates a cross-sectional view of forming a buffer insulation layer in a method for manufacturing a semiconductor device according to an embodiment;

FIG. 9 illustrates a cross-sectional view of forming a buffer insulation layer in a method for manufacturing a semiconductor device according to an embodiment;

FIG. 10 illustrates a cross-sectional view of forming a contact etching stopper layer in a method for manufacturing a semiconductor device according to an embodiment;

FIG. 11 illustrates a cross-sectional view of forming a contact etching stopper layer in a method for manufacturing a semiconductor device according to an embodiment;

FIG. 12 illustrates a plan view of forming a contact plug in a method for manufacturing a semiconductor device according to an embodiment;

FIG. 13 illustrates a cross-sectional view of forming a contact plug in a method for manufacturing a semiconductor device according to an embodiment;

FIG. 14 illustrates a cross-sectional view of a semiconductor device according to an embodiment;

FIGS. 15-16 illustrate graphs of electrical characteristics in a semiconductor device according to an embodiment;

FIG. 17 illustrates a schematic plan view of a memory module including a semiconductor device according to an embodiment;

FIG. 18 illustrates a schematic view of a memory card including a semiconductor device according to an embodiment; and

FIG. 19 illustrates a schematic view of a system including a semiconductor device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer (or element) is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

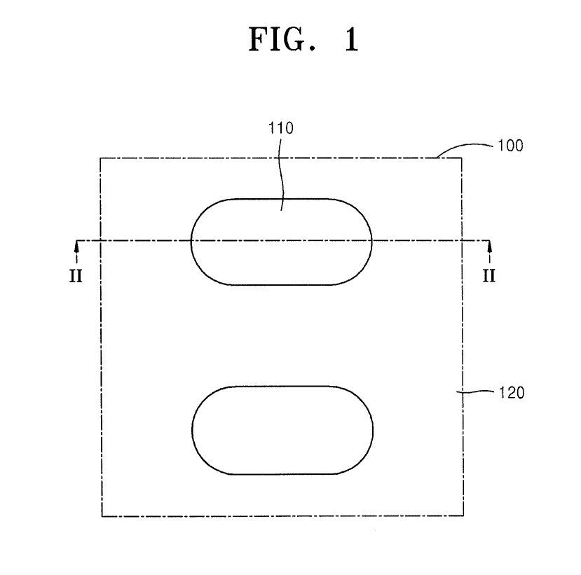

FIG. 1 illustrates a plan view of an operation of forming a trench 120 in a manufacturing method of a semiconductor device according to an example embodiment. Referring to FIG. 1, the trench 120 may be formed in a semiconductor substrate 100 to define a plurality of active areas 110. In order to form the trench 120, a mask pattern (not shown) covering the active areas 110 may be formed. The trench 120 may be formed by removing a portion of the semiconductor substrate 100 by using the mask pattern as an etching mask. The mask pattern may include, e.g., a nitride.

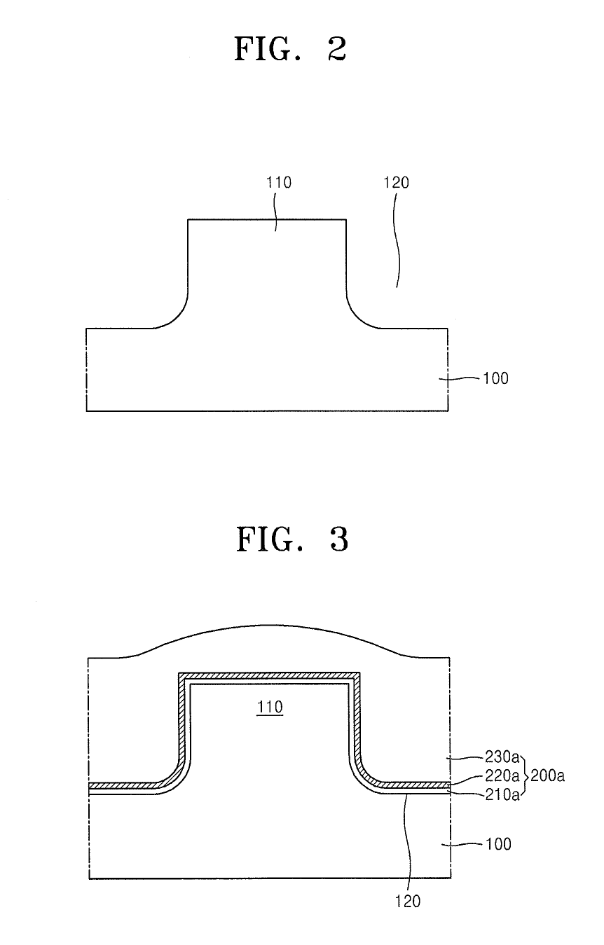

FIG. 2 illustrates a cross-sectional view of an operation of forming a trench in a manufacturing method of a semiconductor device according to an example embodiment. In detail, FIG. 2 is a cross-sectional view taken along a line II-II of FIG. 1.

Referring to FIG. 2, the active areas 110 may be defined by the trench 120 formed in the semiconductor substrate 100. The active areas 110 indicate an upper surface of the semiconductor substrate 100, and portions that are adjacent to the upper surface defined by the trench 120. In the trench 120, a device isolation layer which will be described later may be formed.

FIG. 3 illustrates a cross-sectional view of an operation of forming an insulation material layer 200a in a manufacturing method of a semiconductor device according to an example embodiment. Referring to FIG. 3, the insulation material layer 200a, including a first oxide layer 210a, a liner nitride layer 220a, and a second oxide layer 230a, may be formed on the semiconductor substrate 100, which includes inner surfaces of the trench 120. The first oxide layer 210a and the liner nitride layer 220a may be formed, e.g., sequentially, to cover the inner surfaces of the trench 120, i.e., lateral surfaces and bottom surfaces of the trench 120. The second oxide layer 230a may be formed at least to fill, e.g., completely fill, the trench 120. For example, the first oxide layer 210a and/or the liner nitride layer 220a may be optional, so the insulation material layer 200a may be formed to include only the second oxide layer 230a.

When the mask pattern described with reference to FIG. 1 is formed, i.e., the mask pattern for forming the trench 120, the first oxide layer 210a may be formed only on the inner surfaces of the trench 120 and not on the mask pattern. In other words, the mask pattern may remain on the semiconductor substrate 100 after formation of the trench 120, i.e., during formation of the insulation material layer 200a. In this case, the liner nitride layer 220a may have a relatively small thickness compared to a thickness of the mask pattern. Thus, portions of the liner nitride layer 220a formed on the mask pattern may be treated as a portion of the mask pattern.

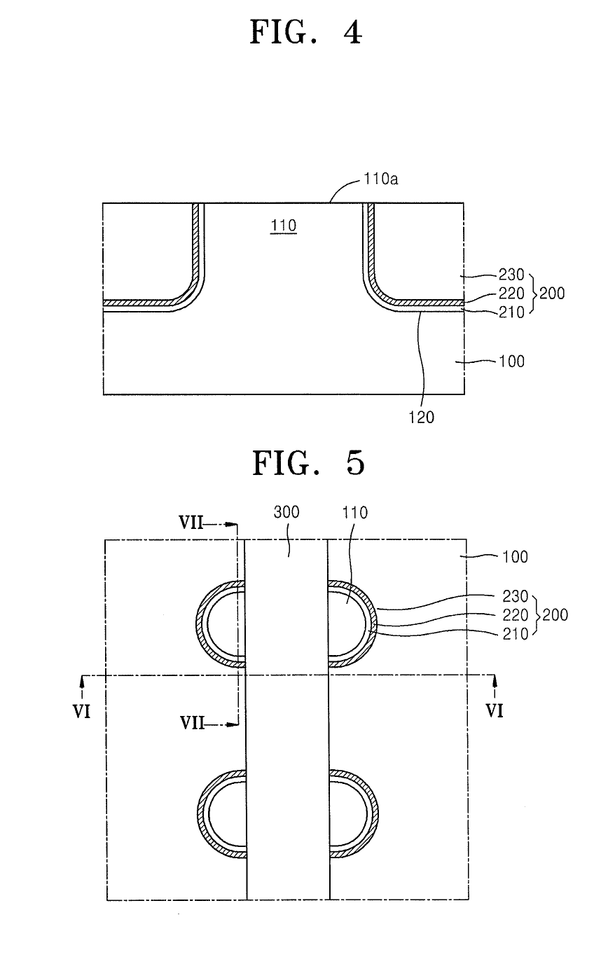

FIG. 4 illustrates a cross-sectional view of an operation of forming a device isolation layer 200 in a manufacturing method of a semiconductor device according to an example embodiment. Referring to FIGS. 3 and 4, a portion of the insulation material layer 200a may be removed to form the device isolation layer 200. In order to form the device isolation layer 200, a chemical mechanical polishing (CMP) method may be used. For example, when the mask pattern described with reference to FIG. 1 is formed, a portion of the insulation material layer 200a may be removed by using the mask pattern as an etching stopper layer to form the device isolation layer 200. In this case, when the mask pattern is removed after forming the device isolation layer 200, an upper surface of the device isolation layer 200 may be higher than an upper surface of the active area 110. In another example, the insulation material layer 200a may cover the entire semiconductor substrate 100 (FIG. 3), followed by CMP for exposing an upper surface 110a of the active area 110 (FIG. 4).

As illustrated in FIG. 4, the first oxide layer 210a, the line nitride layer 220a, and the second oxide layer 230a of the insulation material layer 200a may be respectively formed into a trench buffer oxide layer 210, a trench liner nitride layer 220, and a buried oxide layer 230 of the device isolation layer 200. Accordingly, the device isolation layer 200 may be formed in the trench 120, and the trench buffer oxide layer 210 and the trench liner nitride layer 220 may sequentially cover the inner surfaces of the trench 120. The trench 120 may be completely filled by the buried oxide layer 230.

Consequently, the active area 110 may be defined by the device isolation layer 200. That is, a portion of the semiconductor substrate 100 that is exposed, i.e., where the device isolation layer 200 is not formed, may be defined as the active areas 110.

As illustrated in FIG. 4, upper surfaces of the trench buffer oxide layer 210, trench liner nitride layer 220, buried oxide layer 230, and active area 110 may be substantially level. Further, as illustrated in FIGS. 4 and 5, the device isolation layer 220, e.g., each of the trench buffer oxide layer 210, trench liner nitride layer 220, and buried oxide layer 230, may surround, e.g., completely surround an entire perimeter of, each active area 110.

FIG. 5 illustrates a plan view of an operation of forming a gate structure for a manufacturing method of a semiconductor device according to an example embodiment. Referring to FIG. 5, a gate structure, e.g., a gate line structure 300, may be arranged on the semiconductor substrate 100 to cross the active areas 110. For example, if a major axis of each active area 110 extends along a first direction, a major axis of the line structure 300 may extend along a second direction substantially perpendicular to the first direction, e.g., to cross a plurality of active areas 110 spaced apart from each other along the second direction. In addition, a gate insulation layer (not shown) may be formed on the active areas 110 before forming the gate line structure 300, such that the gate insulation layer may be disposed between the active areas 110 and the gate line structure 300.

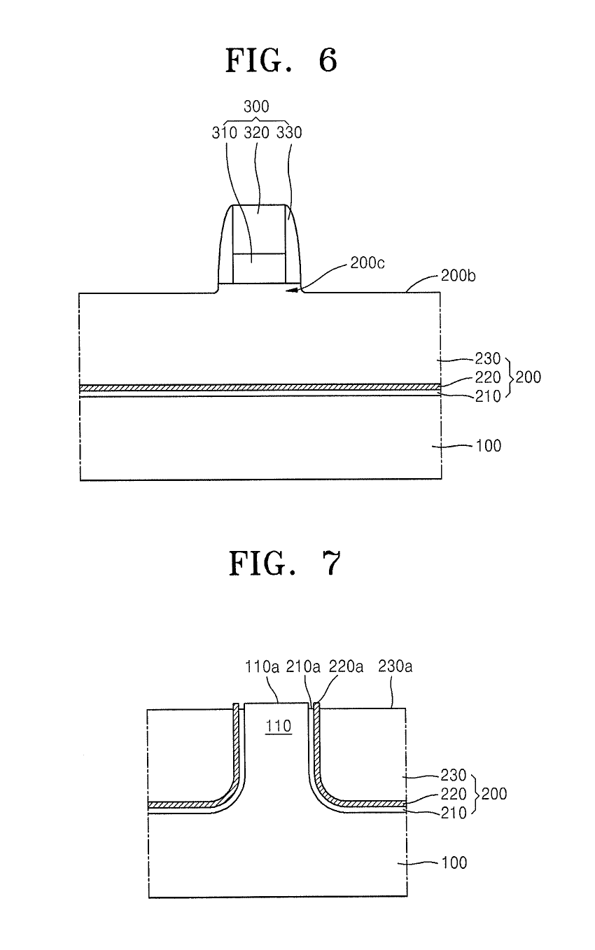

FIG. 6 illustrates a cross-sectional view of forming the gate line structure 300. In detail, FIG. 6 illustrates a cross-sectional view along line VI-VI of FIG. 5. It is noted that FIG. 6 illustrates the gate line structure 300 in a region of the device isolation layer 200.

Referring to FIGS. 5 and 6, the gate line structure 300 may be formed to extend not only on the active areas 110 but also on the device isolation layer 200. The gate line structure 300 may include a conductive gate line 310, a capping layer 320, and a spacer layer 330. The conductive gate line 310 may be formed, e.g., of a metal or a doped polysilicon. The capping layer 320 may be formed of an insulation material, e.g., a nitride. The spacer layer 330 may be formed of an insulation material, e.g., a nitride or an oxide.

The spacer layer 330 may be a single layer, e.g., as illustrated in FIG. 6, or may have a multi-layer structure, e.g., formed of a nitride and an oxide. For example, the spacer layer 330 may have a structure in which an oxide layer is surrounded by at least two nitride layers.

The spacer layer 330 may be formed by forming a preliminary spacer material layer (not shown) covering the semiconductor substrate 100 and then leaving behind portions formed on sides of the conductive gate line 310 and the capping layer 320, e.g., by using an etch-back operation. That is, the spacer layer 330 may be formed to cover the sides of the conductive gate line 310 and the capping layer 320.

It is noted that due to various operations that may be performed after formation of the device isolation layer 200, i.e., after the stage illustrated in FIG. 4, or after formation of the gate line structure 300, i.e., after the stage illustrated in FIGS. 5-6, some portions of the device isolation layer 200 may be removed. For example, portions of an initial upper surface of the device isolation layer 200 may be removed, e.g., due to cleaning, ion-implantation, and/or use of a sacrificial layer for improving interface characteristics. When portions of the initial upper surface of the device isolation layer 200 are removed, an upper surface of the device isolation layer 200 may be lower than the upper surface 110a of the active areas 110. Further, the upper surface 200b of the device isolation layer 200 not covered by the gate line structure 300 may be lower than a portion 200c of the device isolation layer 200 covered by the gate line structure 300 (FIG. 6).

FIG. 7 illustrates a cross-sectional view of an operation of forming the gate line structure 300 for a manufacturing method of a semiconductor device according to an embodiment. In detail, FIG. 7 illustrates an enlarged cross-sectional view along line VII-VII of FIG. 5.

Referring to FIG. 7, upper surfaces 210a and 230a of the trench buffer oxide layer 210 and the buried oxide layer 230 of the device isolation layer 200 may be lower than an upper surface 220a of the trench liner nitride layer 220. For example, when an amount of nitride lost, e.g., due to cleaning, ion-implantation, etc., is smaller than an amount of oxide lost, the trench buffer oxide layer 210 and the buried oxide layer 230 may have upper surfaces that are lower than the upper surface 220a of the trench liner nitride layer 220. For example, the upper surfaces 210a and 230a of the trench buffer oxide layer 210 and the buried oxide layer 230, respectively, may be lower than the upper surface 110a of the active area 110.

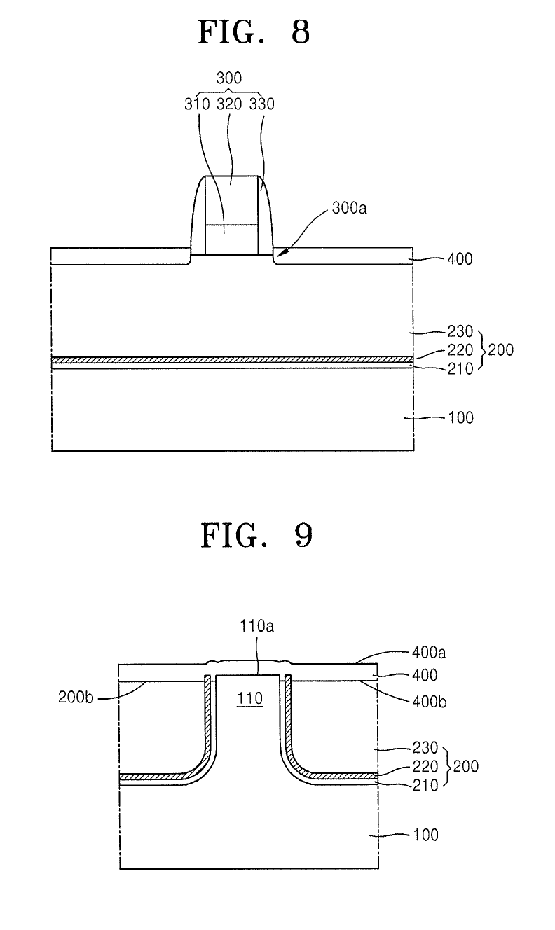

FIG. 8 illustrates a cross-sectional view of an operation of forming a buffer insulation layer in a manufacturing method of a semiconductor device according to an embodiment. In detail, FIG. 8 illustrates a cross-sectional view taken along a line corresponding to the line VI-VI of FIG. 5.

Referring to FIG. 8, a buffer insulation layer 400 may be formed on the semiconductor substrate 100. The buffer insulation layer 400 may be formed of, e.g., an oxide. In detail, the buffer insulation layer 400 may be formed on a portion of the semiconductor substrate 100 that is not covered by the gate line structure 300, so as to contact only a portion of a side of the gate line structure 300. In this case, as illustrated in FIG. 8, the buffer insulation layer 400 may be formed to contact a lower portion 300a of the gate line structure 300, e.g., only a lower portion of a lateral lower side of the gate line structure 300.

For example, the buffer insulation layer 400 may be formed by forming a preliminary buffer layer on the entire surface of the semiconductor substrate 100 and, subsequently, removing a portion of the preliminary buffer layer so as to expose a majority of the gate line structure 300. That is, an upper surface and a majority of lateral sides of the gate line structure 300 may be exposed, while the buffer insulation layer 400 may overlap the lower portion 300a of the gate line structure 300. In another example, the buffer insulation layer 400 may be selectively formed on the semiconductor substrate 100 and/or the device isolation layer 200.

For example, when the semiconductor substrate 100 is formed of silicon and the trench buffer oxide layer 210 and the buried oxide layer 230 of the device isolation layer 200 are formed of silicon oxide, the buffer insulation layer 400 may be selectively formed on the silicon and the silicon oxide. In this case, when a surface of the gate line structure 300, i.e., surfaces of the capping layer 320 and the spacer layer 330, is a nitride, the buffer insulation layer 400 may not be formed on the surface of the gate line structure 300. However, the buffer insulation layer 400 formed on the silicon and the silicon oxide may contact a portion of a lateral lower side of the spacer layer 330. A side of the spacer layer 330 contacted by the buffer insulation layer 400 may be opposite to a surface of the spacer layer 330 contacting the conductive gate line 310 and the capping layer 320. Also, a portion of the trench liner nitride layer 220 of the device isolation layer 200 that is exposed between the trench buffer oxide layer 210 and the buried oxide layer 230 has a relatively smaller width than those of the trench buffer oxide layer 210 and the buried oxide layer 230, and thus, the trench liner nitride layer 220 may be completely covered by the buffer insulation layer 400 formed on the trench buffer oxide layer 210 and the buried oxide layer 230.

FIG. 9 illustrates a cross-sectional view of an operation of forming the buffer insulation layer 400 in a manufacturing method of a semiconductor device according to an example embodiment. In detail, FIG. 9 illustrates an enlarged cross-sectional view taken along a line corresponding to line VII-VII of FIG. 5 after forming the buffer insulation layer 400.

Referring to FIG. 9, the buffer insulation layer 400 may be formed to cover the device isolation layer 200 and the active areas 110 on the semiconductor substrate 100. The buffer insulation layer 400 may be formed such that a portion of the buffer insulation layer 400 formed on the upper surface 200b of the device isolation layer 200, i.e., which is lower than the upper surface 110a of the active areas 110, may be higher than the upper surface 110a of the active areas 110. That is, the thickness of the buffer insulation layer 400 may be adjusted, such that an upper surface 400a of the buffer insulation layer 400 may be higher than the upper surface 110a of the active areas 110. It is noted, however, that when portions of the device isolation layer 200 are removed, i.e., as was discussed previously with reference to FIG. 6, a portion of the buffer insulation layer 400 that is formed on the device isolation layer 200 may have a bottom surface 400b, i.e., a surface opposite the upper surface 400a, that is lower than the upper surface 110a of the active areas 110.

Referring to FIGS. 8 and 9, the buffer insulation layer 400 may be formed to cover portions of the active areas 110 and the device isolation layer 200 of the semiconductor substrate 100 that is not covered by the gate line structure 300, i.e., exposed portions of the active areas 110 and device isolation layer 200. That is, the buffer insulation layer 400 may be formed to cover a lateral lower side of the gate line structure 300, i.e., a lateral lower side of the spacer layer 330 and the exposed portions of the active areas 110 and the device isolation layer 200.

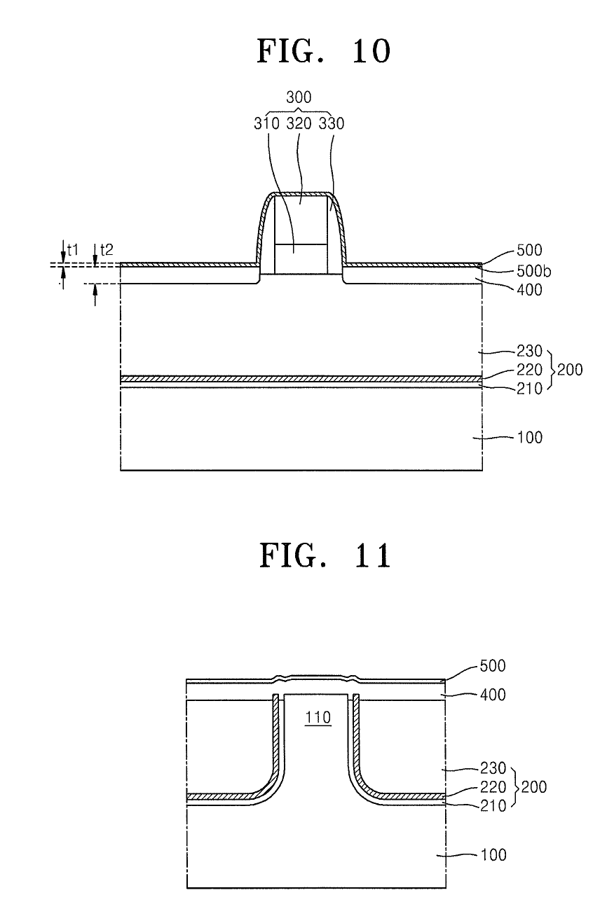

FIG. 10 illustrates a cross-sectional view of an operation of forming a contact etching stopper layer 500 in a manufacturing method of a semiconductor device according to an exemplary embodiment. In detail, FIG. 10 illustrates a cross-sectional view taken along a line corresponding to line VI-VI of FIG. 5 after forming the contact etching stopper layer 500.

Referring to FIG. 10, the contact etching stopper layer 500 may be formed, e.g., conformally, on the semiconductor substrate 100 to cover the buffer insulation layer 400. The contact etching stopper layer 500 may be formed, e.g., of a nitride. For example, if the capping layer 320 and the spacer layer 330 of the gate line structure 300 are formed of a nitride, when the contact etching stopper layer 500 is formed of a same material, i.e., of nitride, on the entire semiconductor substrate 100, the contact etching stopper layer 500 formed on the capping layer 320 and the spacer layer 330 may perform the same function as those of the capping layer 320 and the spacer layer 330, i.e., formation of the contact etching stopper layer 500 on the gate line structure 300 does not affect the function of the gate line structure 300 or its spacer layer 330. Accordingly, the contact etching stopper layer 500 may be formed to cover both the buffer insulation layer 400 and the gate line structure 300.

A second thickness t2, i.e., a thickness of the buffer insulation layer 400, may be the same as a first thickness t1, i.e., a thickness of the contact etching stopper layer 500. Alternatively, as illustrated in FIG. 10, the second thickness t2 may be greater than the first thickness t1. That is, the thickness of the buffer insulation layer 400 may be equal to or larger than the thickness of the contact etching stopper layer 500. When the buffer insulation layer 400 is thicker than the contact etching stopper layer 500, the second thickness t2 may be, e.g., three times thicker than the first thickness t1 or more.

The contact etching stopper layer 500 may be formed on, e.g., directly on, the buffer insulation layer 400, e.g., on the upper surface 400a of the buffer insulation layer 400. Therefore, when the upper surface 400a of the buffer insulation layer 400 is formed to be higher than the upper surface 110a of the active areas 110, the contact etching stopper layer 500 may be formed to have a bottom surface 500b that is higher than the upper surface 110a of the active areas 110.

FIG. 11 illustrates a cross-sectional view of an operation of forming a contact etching stopper layer 500 in a manufacturing method of a semiconductor device according to an example embodiment. In detail, FIG. 11 illustrates an enlarged cross-sectional view taken along a line corresponding to line VII-VII of FIG. 5 after forming the contact etching stopper layer 500.

Referring to FIG. 11, the active areas 110 and the contact etching stopper layer 500 may be separated by the buffer insulation layer 400. Therefore, electrical characteristics of a semiconductor device according to example embodiments may be improved.

In general, when an active area and a contact etching stopper layer are close to each other in a conventional semiconductor device, generated hot electrons may accumulate in the contact etching stopper layer adjacent to the active areas, and accordingly, holes may accumulate in a boundary portion of the active areas due to the accumulated hot electrons. Due to the holes accumulated in the boundary portion of the active areas, electrical characteristics of the conventional semiconductor device may be decreased.

However, when a distance between the active areas 110 and the contact etching stopper layer 500 according to example embodiments is increased, e.g., by forming the buffer insulation layer 400 therebetween, the accumulation of hot electrons in the contact etching stopper layer 500 may be minimized. Therefore, hot electron induced punch-through (HEIP) may be minimized.

Also, due to the buffer insulation layer 400, the trench liner nitride layer 220 and the contact etching stopper layer 500 may not be folded but spaced apart from each other. That is, the trench liner nitride layer 220 and the contact etching stopper layer 500 may be spaced apart from each other, with the buffer insulation layer 400 therebetween. Accordingly, even when hot electrons are accumulated in the trench liner nitride layer 220, transfer of the accumulated hot electrons to the contact etching stopper layer 500 may be prevented or substantially minimized.

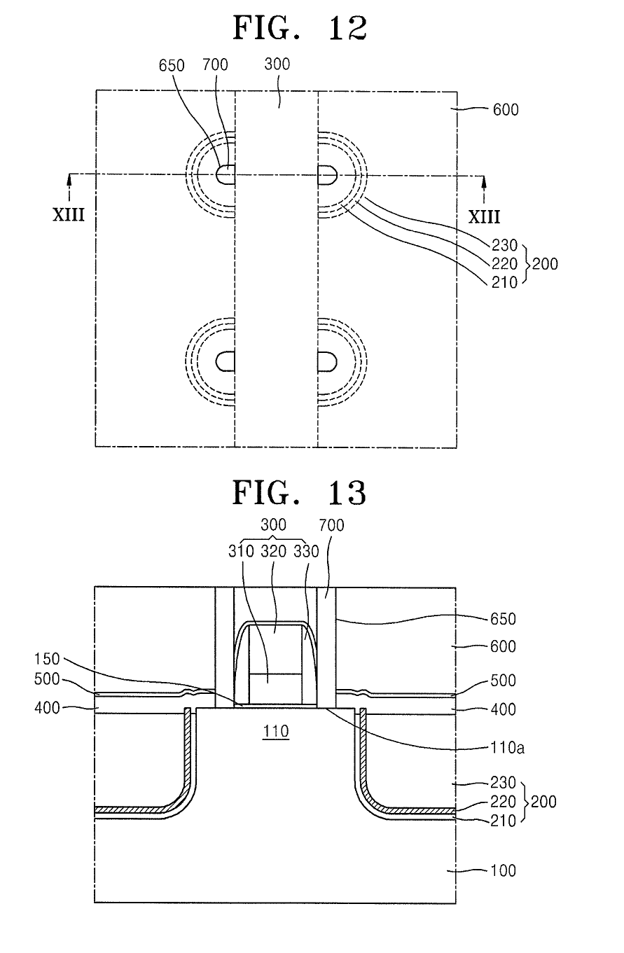

FIG. 12 illustrates a plan view of an operation of forming a contact plug 700 in a manufacturing method of a semiconductor device according to an example embodiment. Referring to FIG. 12, an interlayer insulation layer 600 may be formed to cover the contact etching stopper layer 500. After forming a contact hole 650 passing through the interlayer insulation layer 600, the contact plug 700 may be formed by filling the contact hole 650.

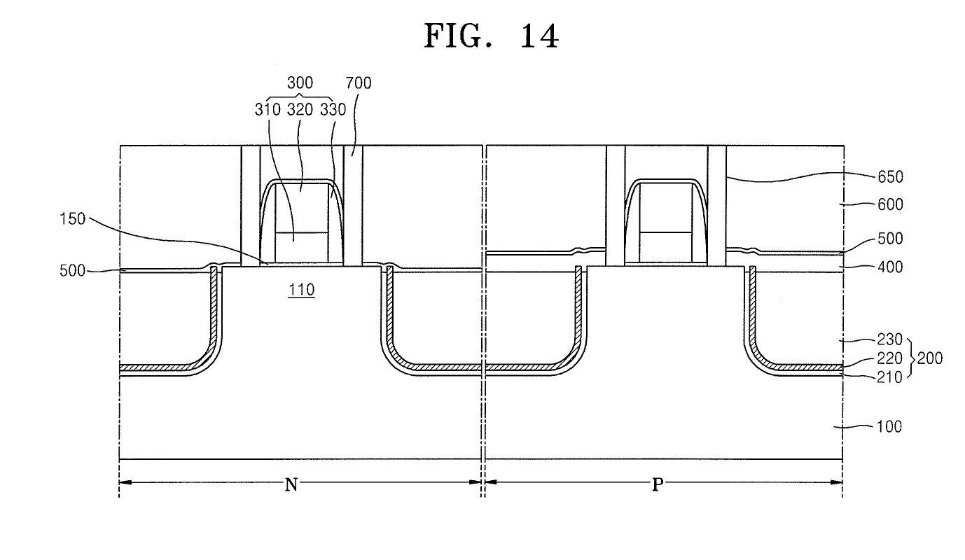

FIG. 13 illustrates a cross-sectional view of an operation of forming a contact plug in a manufacturing method of a semiconductor device according to an example embodiment. In detail, FIG. 13 illustrates a cross-sectional view of FIG. 12 taken along a line XIII-XIII.

Referring to FIG. 13, the contact hole 650 may be pass through the interlayer insulation layer 600, the contact etching stopper layer 500, and the buffer insulation layer 400, so that a portion of the upper surface 110a of the active area 110 of the semiconductor substrate 100 may be exposed. In detail, the interlayer insulation layer 600 may be formed to cover the gate line structure 300. That is, an upper surface of the interlayer insulation layer 600 may be formed to be higher than the upper surface of the gate line structure 300. In order to form the contact hole 650, a mask layer (not shown) may be formed on the interlayer insulation layer 600, and then the interlayer insulation layer 600 may be etched by using the mask layer as an etching mask until the contact etching stopper layer 500 is exposed. Then, the contact hole 650, exposing the active areas 110, may be completed by removing the exposed portion of the contact etching stopper layer 500 and a portion of the buffer insulation layer 400 therebelow.

After forming the contact hole 650, a conductive material (not shown) may be deposited to fill the contact hole 650 and to cover the interlayer insulation layer 600. An etchback process may be performed on the semiconductor substrate 100, i.e., on the conductive material, so that the interlayer insulation layer 600 may be exposed and the conductive material in the contact hole may define the contact plug 700. The contact plug 700 may contact the active areas 110 exposed by the contact hole 650. A silicide may be formed on a surface of the active areas 110 that is exposed before forming the contact plug 700, or a barrier material layer may be formed on an inner surface of the contact hole 650 and the exposed portions of the active areas 110.

Although not shown in the previous drawings, a gate insulation layer 150 may be formed between the active areas 110 and the gate line structure 300, as described with reference to FIG. 5.

FIG. 14 illustrates a cross-sectional view of a semiconductor device according to an example embodiment. Referring to FIG. 14, the semiconductor device may be defined by an n-type area N and a p-type area P. An n-type transistor may be formed in the n-type area N, and a p-type transistor may be formed in the p-type area P.

The p-type area P may have the same structure as illustrated in FIG. 13. The n-type area N is almost the same as the p-type area P except that the buffer insulation layer 400 may not be formed therein. If HEIP described above occurs in the p-type transistor of the p-type area P, the buffer insulation layer 400 may be formed only in the p-type area P in which the p-type transistor is formed. In this case, in the p-type area P, the contact plug 700 passes through all of the interlayer insulation layer 600, the contact etching stopper layer 500, and the buffer insulation layer 400 to be connected to the active areas 110, but in the n-type area N, the contact plug 700 may pass through only the interlayer insulation layer 600 and the contact etching stopper layer 500 to be connected to the active areas 110.

However, the buffer insulation layer 400 may also be formed in the n-type area N for convenience of manufacture or improvement of characteristics of the n-type transistor.

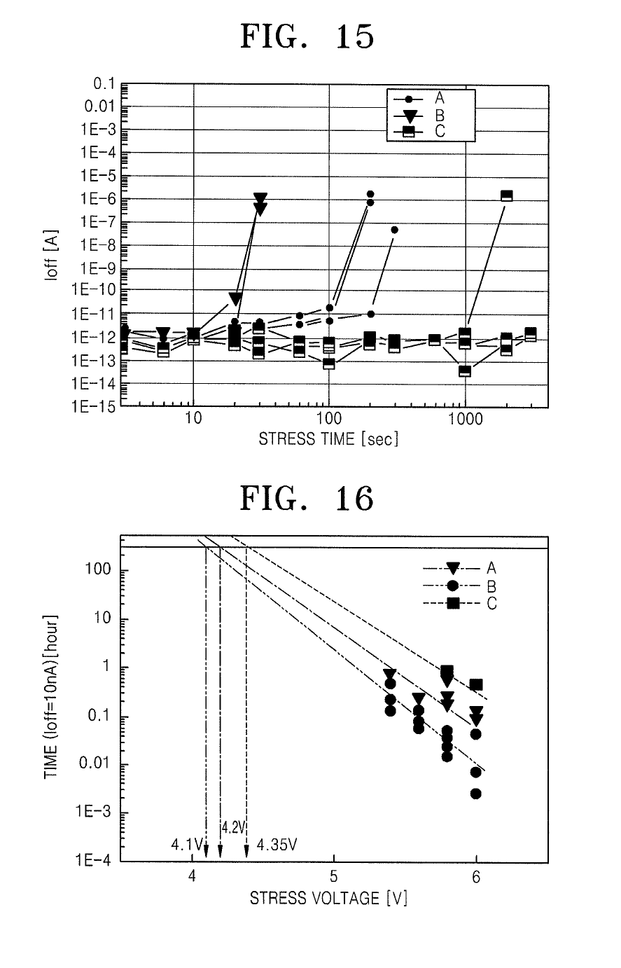

FIG. 15 illustrates a graph of electrical characteristics of a semiconductor device according to an example embodiment. Referring to FIG. 15, an off current Ioff, i.e., current flowing through a turned off transistor over time while a stress voltage is applied, is shown.

As illustrated in FIG. 15, a transistor C of the semiconductor device according to the example embodiment has a longer life time by at least one order, as compared to transistors A and B of conventional semiconductor devices. For reference, one of the transistors A and B of the conventional semiconductor devices having a shorter lifetime (B) than the other indicates that the one transistor has a greater loss in a device isolation layer than the other (A).

FIG. 16 illustrates a graph of electrical characteristics of a semiconductor device according to an example embodiment. Referring to FIG. 16, a stress voltage, which requires 300 hours until an off current Ioff reaches a predetermined value (Ioff=10 nA), is shown. As illustrated in FIG. 16, the transistor C of the semiconductor device according to the example embodiment had a stress voltage increased by at least 0.15 V, as compared to the transistors A and B of the conventional semiconductor devices.

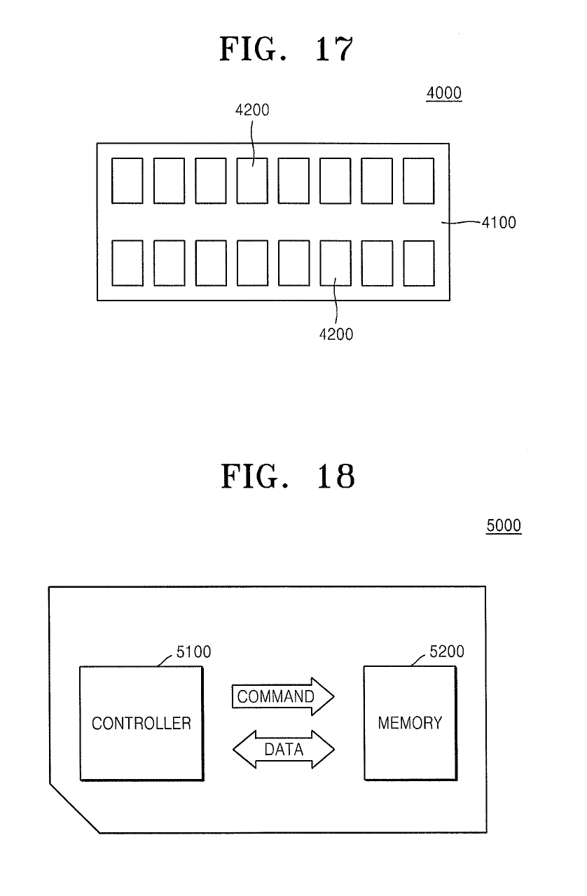

FIG. 17 illustrates a schematic plan view of a memory module 4000 including a semiconductor device according to an example embodiment. Referring to FIG. 17, the memory module 4000 may include a printed circuit board 4100 and a plurality of semiconductor packages 4200.

The plurality of semiconductor packages 4200 may include semiconductor devices according to example embodiments. Also, the plurality of semiconductor packages 4200 may include at least one of the semiconductor devices as described with reference to FIGS. 13 and 14.

The memory module 4000 according to the current embodiment may be a single in-lined memory module (SIMM), i.e., where the plurality of semiconductor packages 4200 are mounted only on one of surfaces of the printed circuit board 4100, or dual in-lined memory module (DIMM), i.e., where the plurality of semiconductor packages 4200 are mounted on two surfaces of the printed circuit board 4100. Also, the memory module 4000 may be a fully buffered DIMM including an advanced memory buffer (AMB) that provides signals from the outside to each of the plurality of semiconductor packages 4200.

FIG. 18 illustrates a schematic view of a memory card 5000 including a semiconductor device according to an example embodiment. Referring to FIG. 18, the memory card 5000 may be disposed such that a controller 5100 and a memory 5200 exchange electrical signals with each other. For example, when the controller 5100 gives a command, the memory 5200 may transmit data.

The memory 5200 may include semiconductor devices according to an embodiment. Also, the memory 5200 may include at least one of the semiconductor devices described with reference to FIGS. 13 and 14. The memory card 5000 may be any of various memory cards, e.g., a memory stick card, a smart media card (SM), a secure digital card (SD), a mini-secure digital card (mini SD), or a multimedia card (MMC).

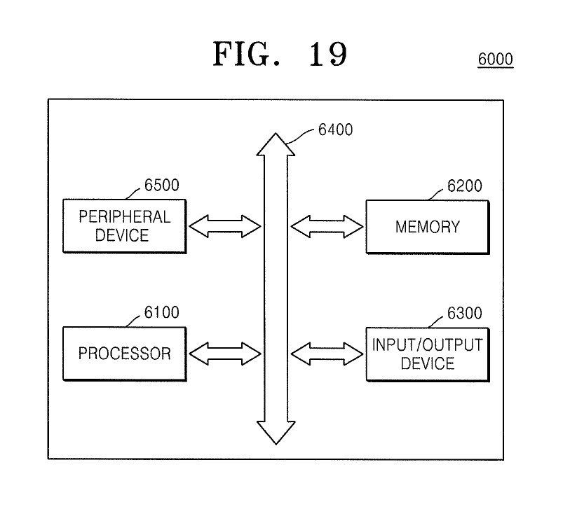

FIG. 19 illustrates a schematic view of a system 6000 including a semiconductor device according to an example embodiment. In the system 6000, a processor 6100, an input/output device 6300, and a memory 6200 may perform data communications with one another via a bus 6400. Also, the system 6000 may include a peripheral device 6500, e.g., a floppy disk drive or a compact disk (CD) ROM drive.

The memory 6200 of the system 6000 may be a random access memory (RAM) or a read only memory (ROM). The memory 6200 may include semiconductor devices according to example embodiments. Also, the memory 6200 may include at least one semiconductor device described with reference to FIGS. 13 and 14. The memory 6200 may store codes and data for operating the processor 6100. The system 6000 may be used in, e.g., mobile phones, MP3 players, navigation devices, portable multimedia players (PMP), solid state disks (SSD), or household appliances.

Example embodiments have been disclosed herein, and although specific terms are employed, they are used and are to be. Accordingly, it will be understood by those of skill in the art that various changes in form and details may be made without departing from the spirit and scope of the present invention as set forth in the following claims.

What is claimed is:

1. A semiconductor device, comprising:
a semiconductor substrate including a plurality of active areas defined by a device isolation layer;
a gate line structure crossing the plurality of active areas;
a buffer insulation layer on the semiconductor substrate, the buffer insulation layer contacting a portion of a side of the gate line structure;
a contact etching stopper layer on the buffer insulation layer; and
a contact plug passing through the buffer insulation layer and the contact etching stopper layer to be connected to the plurality of active areas.

2. The semiconductor device as claimed in claim 1, wherein the contact etching stopper layer covers the gate line structure.

3. The semiconductor device as claimed in claim 1, wherein the buffer insulation layer has a predetermined thickness, the predetermined thickness overlapping a portion of a lateral lower side of the gate line structure.

4. The semiconductor device as claimed in claim 1, wherein the gate line structure includes:
a conductive gate line;
a capping layer on the conductive gate line; and
a spacer layer covering sides of the conductive gate line and the capping layer.

5. The semiconductor device as claimed in claim 4, wherein the buffer insulation layer overlaps a portion of a side of the spacer layer.

6. The semiconductor device as claimed in claim 5, wherein the buffer insulation layer has a predetermined thickness, the predetermined thickness overlapping a portion of a lateral lower side of the spacer layer.

7. The semiconductor device as claimed in claim 4, wherein the contact etching stopper layer is on the capping layer and the spacer layer.

8. The semiconductor device as claimed in claim 1, wherein the contact etching stopper layer has a bottom surface that is higher than an upper surface of the active areas.

9. The semiconductor device as claimed in claim 1, wherein an upper surface of the buffer insulation layer is higher than an upper surface of the active areas.

10. The semiconductor device as claimed in claim 1, wherein a portion of the buffer insulation layer on the device isolation layer has a bottom surface that is lower than an upper surface of the active areas.

11. The semiconductor device as claimed in claim 1, wherein the semiconductor substrate includes a trench with a device isolation layer therein, the device isolation layer including:
a trench buffer oxide layer and a trench liner nitride layer sequentially covering inner surfaces of the trench, and
a buried oxide layer filling the trench.

12. The semiconductor device as claimed in claim 11, wherein the trench liner nitride layer and the contact etching stopper layer are spaced apart from each other, the buffer insulation layer being between the trench liner nitride layer and the contact etching stopper layer.

13. The semiconductor device as claimed in claim 1, wherein a thickness of the buffer insulation layer is equal to or larger than a thickness of the contact etching stopper layer.

14. The semiconductor device as claimed in claim 1, further comprising an interlayer insulation layer covering the contact etching stopper layer, the contact plug passing through the interlayer insulation layer to be connected to the active areas.

15. The semiconductor device as claimed in claim 14, wherein an upper surface of the interlayer insulation layer is higher than an upper surface of the gate line structure.

16. The semiconductor device as claimed in claim 1, wherein the buffer insulation layer includes an oxide, and the contact etching stopper layer includes a nitride.

17. The semiconductor device as claimed in claim 1, wherein the buffer insulation layer surrounds a lower portion of the gate line structure.

18. A semiconductor device, comprising:
a gate structure on a semiconductor substrate;
a buffer insulation layer on the semiconductor substrate, a portion of the buffer insulation layer overlapping an active area in the semiconductor substrate;
a contact etching stopper layer on the buffer insulation layer, the buffer insulation layer separating the active area and the contact etching stopper layer; and
a contact plug passing through the buffer insulation layer and the contact etching stopper layer to be connected to the active area.

19. A semiconductor device, comprising:
a semiconductor substrate including an n-type area with an n-type transistor, a p-type area with a p-type transistor, and a plurality of active areas defined by a device isolation layer;
a gate line structure crossing the plurality of active areas;
a buffer insulation layer in the p-type area of the semiconductor substrate, the buffer insulation layer contacting a portion of a side of the gate line structure;
a contact etching stopper layer on the semiconductor substrate and the gate line structure to cover the buffer insulation layer; and
a contact plug passing through the contact etching stopper layer to be connected to the plurality of active areas, the contact plug being in each of the p-type area and the n-type area.

20. The semiconductor device as claimed in claim 19, wherein the contact plug in the p-type area passes through the contact etching stopper layer and the buffer insulation layer to be connected to the plurality of active areas.
